(19) United States
(12) Patent Application Publication
(10) Pub. No.: US 2013/0181113 A1
(43) Pub. Date: Jul. 18, 2013

(54) SOLID-STATE IMAGING EQUIPMENT

(71) Applicant: Yoshitaka EGAWA, Kanagawa-ken (JP)

(72) Inventor: Yoshitaka EGAWA, Kanagawa-ken (JP)

(73) Assignee: KABUSHIKI KAISHA TOSHIBA, Tokyo (JP)

(21) Appl. No.: 13/603,276

(22) Filed: Sep. 4, 2012

(30) Foreign Application Priority Data
Jan. 12, 2012 (JP) 2012-004056

(51) Int. Cl. H04N 5/335; H01L 31/18; H01L 31/0232

(52) U.S. Cl. 250/208.1; 257/432; 438/69; 257/E31.127

(57) ABSTRACT

According to one embodiment, an image sensor, which may form part of a solid-state imaging device, such as a camera, comprises a photoelectric conversion element array, a light collection optical array, and a mirror unit that separates colors according to wavelength. Of the light that enters the image sensor, the colors are separated and at least a first colored ray is transmitted by the mirror unit to a dedicated photoelectric conversion element. The mirror unit reflects at least a second and third colored ray toward a laminate photoelectric conversion element for the second and third colored ray.

### CROSS-REFERENCE TO RELATED APPLICATION

This application is based upon and claims the benefit of priority from Japanese Patent Application No. 2012-004056, filed Jan. 12, 2012; the entire contents of which are incorporated herein by reference.

### FIELD

Embodiments described herein relate to a solid-state imaging device.

### BACKGROUND

In recent years, there has been an ongoing demand for smaller camera modules that are embedded in cell phones and other electronic devices. Image sensors in the camera modules require miniaturization of pixels as well as an increase in the pixel count in order to achieve this smaller size. However, as the pixel size decreases, light quantity also decreases, which decreases the signal level. The decrease in signal level becomes pronounced due to the minimal amount of light that enters the pixel, and degradation of the signal to noise ratio (SNR) becomes problematic. Thus, it is desirable for image sensors to achieve higher sensitivity and resolution through an improvement in light usage efficiency without the use of traditional color separation filters, plural multi-wavelength mirrors for each incident ray, and/or interpolation methods to synthesize a color image produced by the image sensor.

With so-called signal panel type image sensors, photoelectric conversion elements separate and detect each colored ray, and make it possible to synthesize a color image via color reproduction through interpolation. Traditionally, with image sensors, attempts have been made to utilize, as much as possible, light rays that do not contribute to photoelectric conversion, by changing the method with which to separate colors—by absorbing all the rays that do not lead to photoelectric conversion with a colored filter, or some other method.

Image sensors can take on a composition to separate the information for each color in each position by placing three layers red of (R), green (G), and blue (B) photodiodes in the thickness direction of the board. In this case, degradation in color reproducibility could be caused due to insufficient separation among the light rays of different wavelengths, and hence different colors, because the spectral characteristics of the photodiodes could overlap each other between the photodiodes for the R light and G light, and between the photodiodes for the G light and the B light. When executing color matrix arithmetic processing (color reproducibility process) to achieve color reproducibility, an improvement in color reproducibility can be using a large coefficient to be used in the computation large. In this case, making the coefficient large can cause degradation of the SNR (signal to noise ratio), so improving the SNR becomes difficult.

Image sensors can take on a composition that, for example, uses a dichroic mirror placed along the light path of the incident light to separate each colored ray and lead each colored ray to the photoelectric conversion element. For example, when separating each colored ray of red (R), green (G), and blue (B), two types of dichroic mirrors will be placed along the light path. The laminate structure of the dichroic mirror is formed as a thin-film multilayer structure with different refraction indices. Since producing two types of dichroic mirrors doubles the amount of work required to form the laminate structures, it would require a long time to produce and cause a spike in production costs.

Since wavelength characteristics depend heavily on the incidence angle, with various incidence angles, the wavelength characteristic of the dichroic mirror can change, for example, around several tens of nanometers. The variability in the spectral characteristic that is produced in this way becomes more apparent by using two types of dichroic mirrors with different wavelength, characteristics and cause degradation in color reproducibility.

### DESCRIPTION OF THE DRAWINGS

FIG. 1 is a cross-sectional diagram of a portion of one embodiment of an image sensor which may be used in a solid-state imaging device.

FIG. 2 is a block diagram that shows the schematic framework of a solid-state imaging device (i.e., a camera) where the image sensor shown in FIG. 1 may be used.

FIG. 3 shows a plan view of one embodiment of a microlens array and a photoelectric conversion element array.

FIG. 4 is a graph showing an example of the spectral characteristic of the dichroic mirror.

FIG. 5 is a schematic diagram explaining the behavior of light that enters the image sensor of FIG. 1.

FIG. 6 is a cross-sectional diagram of the relevant elements in an example of a production method of the image sensor of FIG. 1.

FIG. 7 is a cross-sectional diagram of the relevant elements in an example of the production method of the image sensor of FIG. 1.

FIG. 8 is a cross-sectional diagram of the relevant elements in an example of the production method of the image sensor of FIG. 1.

FIG. 9 is a plan view showing an example of a variant embodiment of a microlens array and a photoelectric conversion element array.

FIG. 10 is a cross-sectional diagram of a portion of the image sensor of FIG. 9, which is the solid-state imaging device that may be used in the camera of FIG. 2.

FIG. 11 is a cross section diagram of a portion of another embodiment of an image sensor that may be used in the camera of FIG. 2.

FIG. 12 is a plan view of another embodiment of a microlens array and a photoelectric conversion element array.

FIG. 13 is a graph showing an example of the spectral characteristic of the dichroic mirror of FIG. 11.

FIG. 14 is a diagram explaining the behavior of light that enters the image sensor of FIG. 11.

### DETAILED DESCRIPTION

In general, according to the embodiments, an image sensor as part of a solid-state imaging device according to the embodiments is explained in detail, referring to the attached FIG'S.

According to the embodiment, there is provided a solid-state image device capable of increased sensitivity with improved color separation. The solid-state image device is also capable of increased light usage efficiency and may further reduce manufacturing costs as compared to conventional image sensors.

According to one embodiment of this invention, the solid-state imaging device includes a photoelectric conversion element array, a light collection optical array, and a color separator unit. The photoelectric conversion element array is equipped with at least a photoelectric conversion element dedicated for a first wavelength range (i.e., a first colored ray), one dedicated for a second wavelength range (i.e., a second colored ray), and one dedicated for a third wavelength range (i.e., a third colored ray). The first, second and third wavelength ranges may correspond to the wavelengths of primary colors, such as red (R), green (G) and blue (B). In some embodiments, the photoelectric conversion element array is equipped with a photoelectric conversion element dedicated for a fourth wavelength range that is outside of the RGB wavelength ranges, such as wavelengths corresponding to the infrared (IR) spectra.

The photoelectric conversion element dedicated for the first colored ray detects the first colored ray. The photoelectric conversion element dedicated for the second colored ray detects the second colored ray. The photoelectric conversion element dedicated for the third colored ray detects the third colored ray. The light collection optical array is equipped with light collection optics with respect to the photoelectric conversion elements. The light collection optics focus light provided to the solid-state imaging device. The color separator unit is placed along the path of light that comes out of the light collection optics. The color separator unit comprises a plurality of mirrors disposed in a transparent medium. Of the incident light, the color separator permeates (i.e., transmits), at least, light in the first wavelength range, and reflects light in the second wavelength range and the third wavelength range.

The color separator unit is placed between the light collection optics and the photoelectric conversion element dedicated for the first wavelength range. The color separator unit has an incidence plane tilted with respect to a plane of the principle ray of incident light from the light collection optics. The photoelectric conversion element dedicated for the second wavelength range and the photoelectric conversion element dedicated for the third wavelength range comprise a laminate structure i.e., layer-stacked such that one photoelectric conversion element at least partially overlays another photoelectric conversion element. In the laminate array structure, photoelectric conversion elements dedicated for the second wavelength range are positioned on the incoming energy side of the photoelectric conversion elements dedicated for the third wavelength range. The photoelectric conversion element array also comprises the photoelectric conversion element dedicated for the first wavelength range that is arranged into the array in a laterally spaced-apart relation to the laminate structure.

The light collection optics is positioned to include one part each of the laterally spaced-apart photoelectric conversion element dedicated for the first wavelength range, and the photoelectric conversion element dedicated for the second wavelength range.

### EMBODIMENT 1

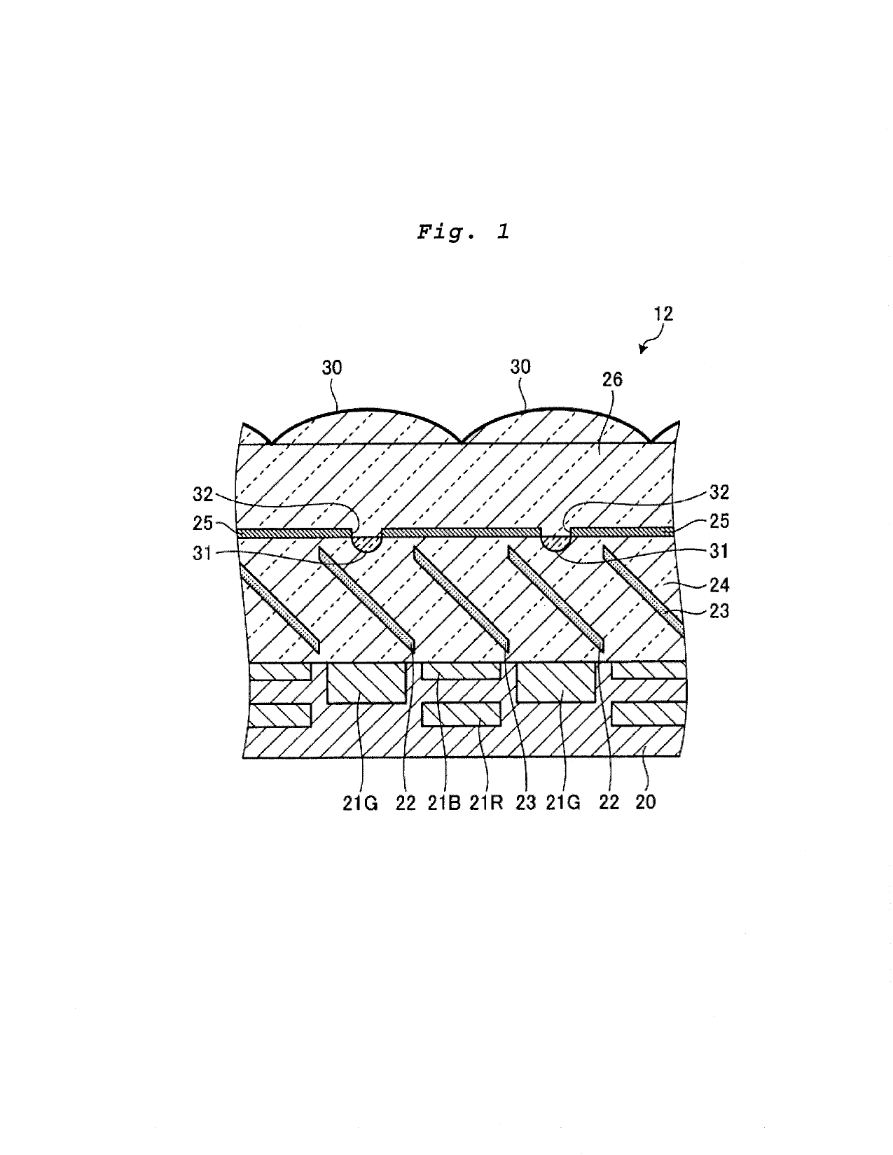

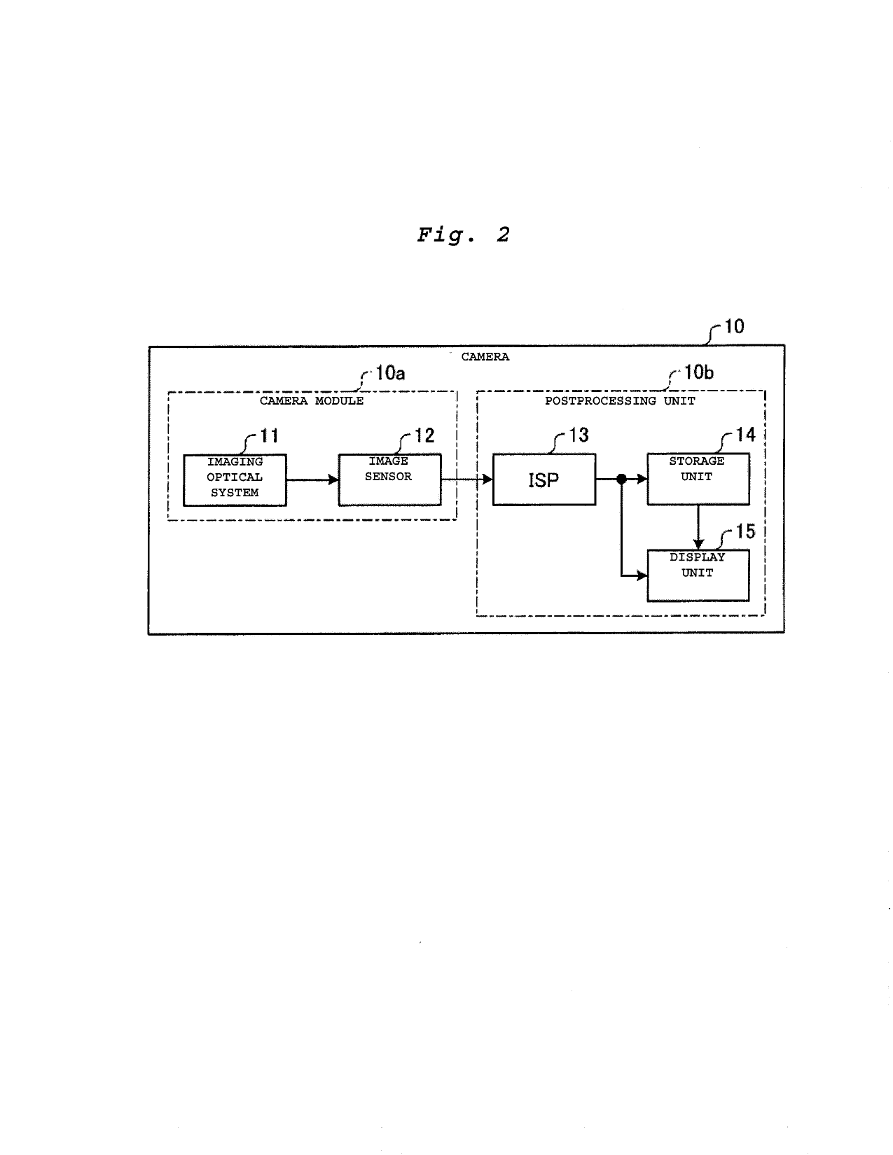

FIG. 1 is a cross-sectional diagram of a portion of an image sensor 12 which may be utilized in a solid-state imaging device according to one embodiment. FIG. 2 is a schematic diagram of a camera 10 as an example of a solid-state imaging device that may utilize the image sensor 12 shown in FIG. 1.

The camera 10 (FIG. 2) comprises a camera module 10a and a post-processing unit 10b. The camera module 10a comprises an imaging optical system 11 and an image sensor 12. The post-processing unit 10b comprises an image signal processor (ISP) 13, storage unit 14 and display unit 15. The camera 10 is, for example, a digital camera. The camera module 10a, besides a digital camera, can be used in electronic devices such as cell phones, as well as other electronic devices equipped with cameras.

The imaging optical system 11 takes light from the photographic subject and forms an image of the subject image. The image sensor 12 obtains an image of the subject image. The ISP 13 conducts the signal processing of the image signals that are generated from the image obtained by the image sensor 12.

The storage unit 14 stores the images that have been subjected to signal processing in the ISP 13. The storage unit 14 outputs the image signal to the display unit 15 in response to user operation, etc. The display unit 15 displays images in response to image signals that are input from the ISP 13 or the storage unit 14. The display unit is, for example, an LCD display.

Referring to FIG. 1, the image sensor 12 comprises a photoelectric conversion element array. The photoelectric conversion element array comprises multiple photoelectric conversion elements 21R, 21G, and 21B. The photoelectric conversion elements 21R, 21G, and 21B are, for example, an N-type photodiode, which are formed on a P-type semiconductor layer 20. Each of the photoelectric conversion elements 21R, 21G, and 21B are laterally spaced from each other within the semiconductor layer 20, and form a repeating pattern on the p type semiconductor layer.

The photoelectric conversion elements 21R and 21B form a stacked laminate structure that sandwiches a portion of the P-type layer of the semiconductor layer 20 therebetween. The photoelectric conversion element 21B is an N-type layer that is disposed in an inset or recess in the in the p type semiconductor layer between the stacks of N-type photoelectric conversion elements 21B and 21R, and the furthest extension of the photoelectric conversion layer 21g from the inset is coplanar with the furthest extension of the photoelectric conversion layer 21B from the underlying p type semiconductor layer. As shown in FIG. 1, this furthest extension of layers 21B and 21G is coplanar with a surface of the p-type semiconductor layer 20. The photoelectric conversion element array is composed of repeating groups of the photoelectric conversion element 21G laterally spaced relative to the laminate structure of the photoelectric conversion element 21R and 21B arranged into an optical array.

In one aspect, the photoelectric conversion element 21G is a photoelectric conversion element dedicated for detection of a first colored ray, such as the G or green light. The photoelectric conversion element 21B is a photoelectric conversion element dedicated for detection of the second colored ray, such as the B or blue light. The photoelectric conversion element 21R is a photoelectric conversion element dedicated for detection of the third colored ray, such as the R or red light. In the laminate structure of the photoelectric conversion elements 21R and 21B, the photoelectric conversion element 21B is layer-stacked on the incoming side of the photoelectric conversion element 21R. In this manner, B light is detected by the photoelectric conversion element 21B while R light passes through the photoelectric conversion element 21B and is detected by the photoelectric conversion element 21R.

The photoelectric conversion elements 21R, 21G, and 21B produce charges that correspond to the amount of incident light received thereon. The photoelectric conversion elements 21R, 21G, and 21B separate and detect each colored ray. The image sensor 12 shall be, for example, a CMOS sensor. This embodiment shall be applicable to both frontside illumination type CMOS image sensors and backside illumination type CMOS image sensors.

According to aspects of the image sensor 12, a microlens array is formed on the surface where the incident light from the imaging optical system 11 enters. The microlens array comprises multiple microlenses 30 that are configured into an array. The microlens 30 functions as a light collection optics that focuses incident light from the imaging optical system 11. The microlens array functions as a light collection optical array that is placed on the incident light side of the photoelectric conversion element array. The microlens 30 is, for example, designed so that light is focused on the optical receiving surface of the photoelectric conversion element 21G.

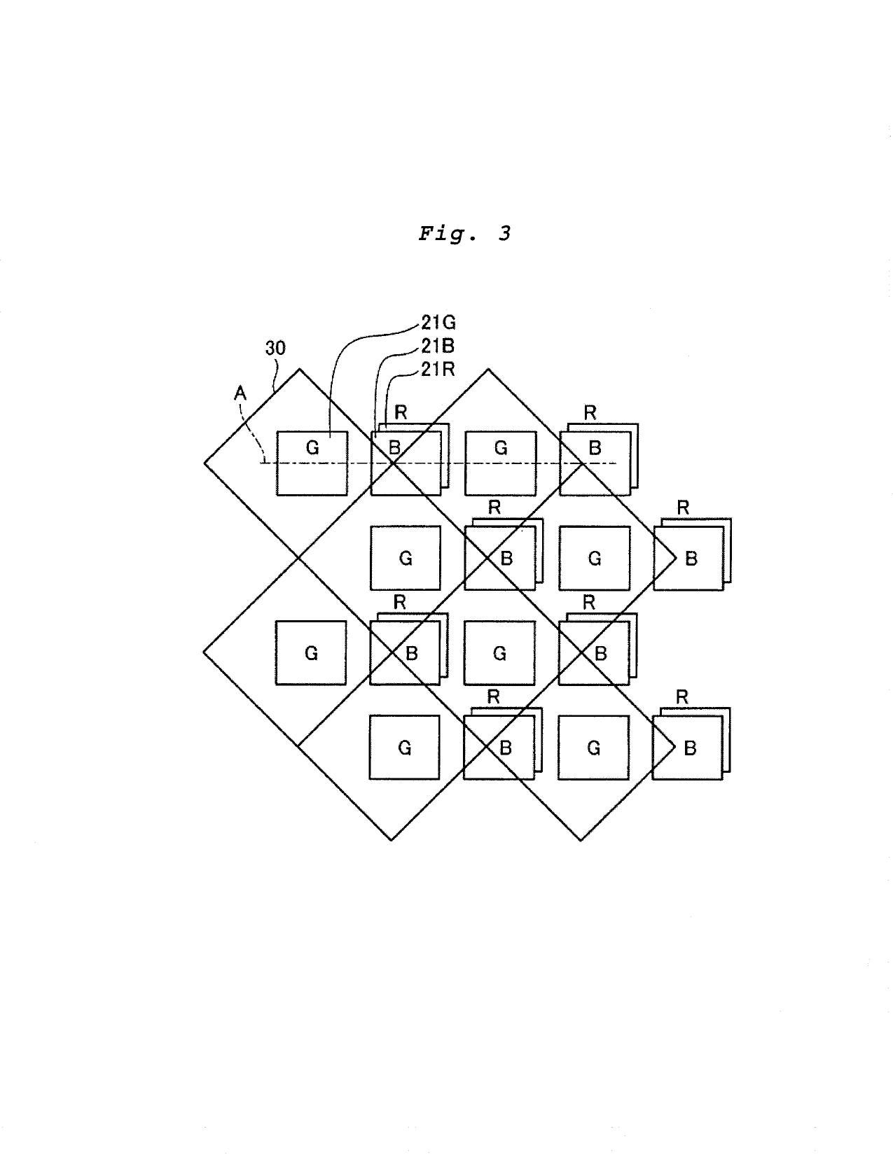

FIG. 3 is a schematic plan view showing positioning of the microlens array and the photoelectric conversion element array. Here, the microlens 30 is shown when viewed from a slight angle on the incident light side of the image sensor 12 and the photoelectric conversion elements 21R, 21G, and 21B that are positioned below the microlens 30. In FIG. 3, the left-right direction on the paper shall be the column direction, and the up-down direction on the paper of FIG. 3 shall be the row direction. Also, the cross-section shown in FIG. 1 corresponds to the cross-section at the dashed line A in FIG. 3.

The photoelectric conversion element 21G, and the laminate structure comprising the photoelectric conversion element 21R and 21B, are arranged so that they form a rectangular array. The photoelectric conversion element 21G extends in a diagonal direction with respect to the column direction and row direction. Similarly, the laminate structure of photoelectric conversion elements 21R and 21B also extends in a diagonal direction.

The microlens 30 is arranged so that the position of the photoelectric conversion element 21G is at or near the center of the microlens 30. The microlens 30 is placed accordingly to include the optical receiving surface of the central photoelectric conversion element 21G and a portion of the optical receiving surface of the photoelectric conversion element 21B that is adjacent to the photoelectric conversion element 21G in the column direction and the row direction. The area of the microlens 30 has a surface roughly the size of two pixels. Due to this, the image sensor 12 is composed so that one microlens 30 corresponds to a combination of photoelectric conversion elements 21R, 21G, and 21B dedicated for each colored ray.

The microlens 30, is positioned in a diagonal direction relative to the photoelectric conversion element 21G that is positioned in the center, and forms an array of rectangle (squares) in an array that is angled about 45 degrees from the rectangular shape of the periphery of the photoelectric conversion element 21. The microlens 30 is, for example, quadrate in shape. The microlens 30 can be, besides a quadrate, for example, an octagon that is a quadrate with its four corners slightly removed, or shaped like a quadrate with its four corners rounded, a rhombus, or a round shape, etc.

Referring again to FIG. 1, the image sensor 12 includes a first transparent layer 24, a light shielding layer 25 and a second transparent layer 26 which are placed between the photoelectric conversion element array and the microlens array. On the light shielding layer 25 there are openings 32 that allow light that has passed from the microlens 30 therethrough in discrete locations. The opening 32 is placed between the center position of the microlens 30 and the center position of the photoelectric conversion element 21G. The light shielding layer 25 shields light that travels from the microlens array side to the photoelectric conversion element array in places besides the opening 32. The light shielding layer 25 is composed, for example, using metal materials such as aluminum.

An inner-layer lens 31 is placed in the openings 32 in the light shielding layer. The inner-layer lens 31 functions as a parallelizing optics that makes the light rays that are focused by the microlens 30 parallel to one another. The first transparent layer 24 is placed between the photoelectric conversion element array and the light shielding layer 25. The first transparent layer 24 transmits light therethrough that enters it from the inner-layer lens 31. The light transmitted through the inner-layer lens 31 may comprise a primary energy ray consisting of R light, G light, and B light, as well as wavelengths outside of the visible spectrum. The second transparent layer 26 is placed between the light shielding layer 25 and the microlens array. The second transparent layer 26 transmits light therethrough that enters it from the microlens 30. The first transparent layer 24 and the second transparent layer 26 are composed of transparent materials such as silicon oxide (e.g., SiO₂).

A dichroic mirror 22 and a reflecting mirror 23 are placed on the first transparent layer 24. The dichroic mirror 22 is placed along the primary energy ray path or direction of light that moves from the microlenses 30 to the first transparent layer 24 via the inner-layer lens 31. Thus, the primary path of light travelling through the lens 31 and first transparent layer is also at an angle of about 45 degrees with respect to the surfaces of the photoelectric conversion layers 21G, B and R facing the lenses 30. The dichroic mirror 22 is tilted so that the incidence plane is roughly at a 45 degree angle with respect to the primary energy ray path that enters from the microlens 30. Of the entered light, the dichroic mirror 22 transmits the G light and reflects the B light and the R light. The dichroic mirror 22 comprises the color separator unit that functions to separate light from the inner-layer lens 31. The dichroic mirror 22 is equipped with a dielectric multilayer that comprises a layer of materials with a high refractive index, for example, titanium oxide (e.g., TiO₂) and a layer of materials with a low refractive index, for example silicon oxide (e.g., SiO₂), in an alternating manner.

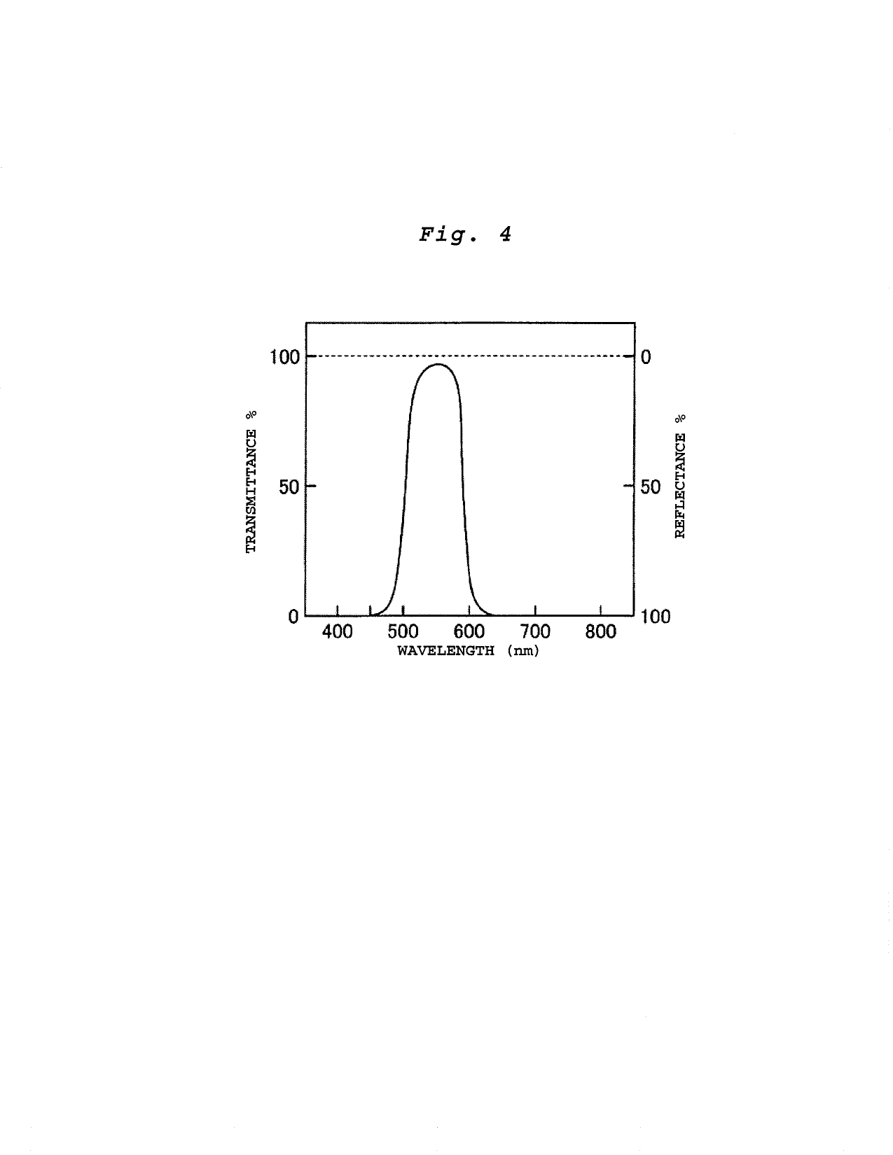

FIG. 4 is a graph showing an example of the spectral characteristic of the dichroic mirror. The dichroic mirror 22, for example, transmits the G light from 490 nm to 580 nm and reflects the B light that is shorter than 490 nm and the R light that is longer than 580 nm. The wavelengths illustrated by this example shall be the half-power wavelength with 50% transmittance.

Referring again to FIG. 1, the reflecting mirror 23 is placed above the photoelectric conversion element 21B and along the path of light composed of secondary energy rays (e.g., B light and R light) that is reflected from the dichroic mirror 22. The reflecting mirror 23 is tilted so that the incidence plane is at a nearly 45 degree angle with respect to the light-receiving surface of the photoelectric conversion element 21B. In one aspect, the incidence plane of the dichroic mirror 22 and the incidence plane of the reflecting mirror 23 are nearly parallel.

The reflecting mirror 23 reflects the B light and the R light that enters from the dichroic mirror 22. The reflecting mirror 23 functions as the reflecting unit that reflects the B light and the R light from the dichroic mirror 22 towards the photoelectric conversion element 21B. The reflecting mirror 23 is composed of highly reflective materials, for example, metal materials such as aluminum, etc., and a dielectric multilayer that has no wavelength selectivity. Additionally or alternatively, the reflecting surface of the reflecting mirror 23 can include a dielectric multilayer having the same wavelength selectivity as the dichroic mirror 22.

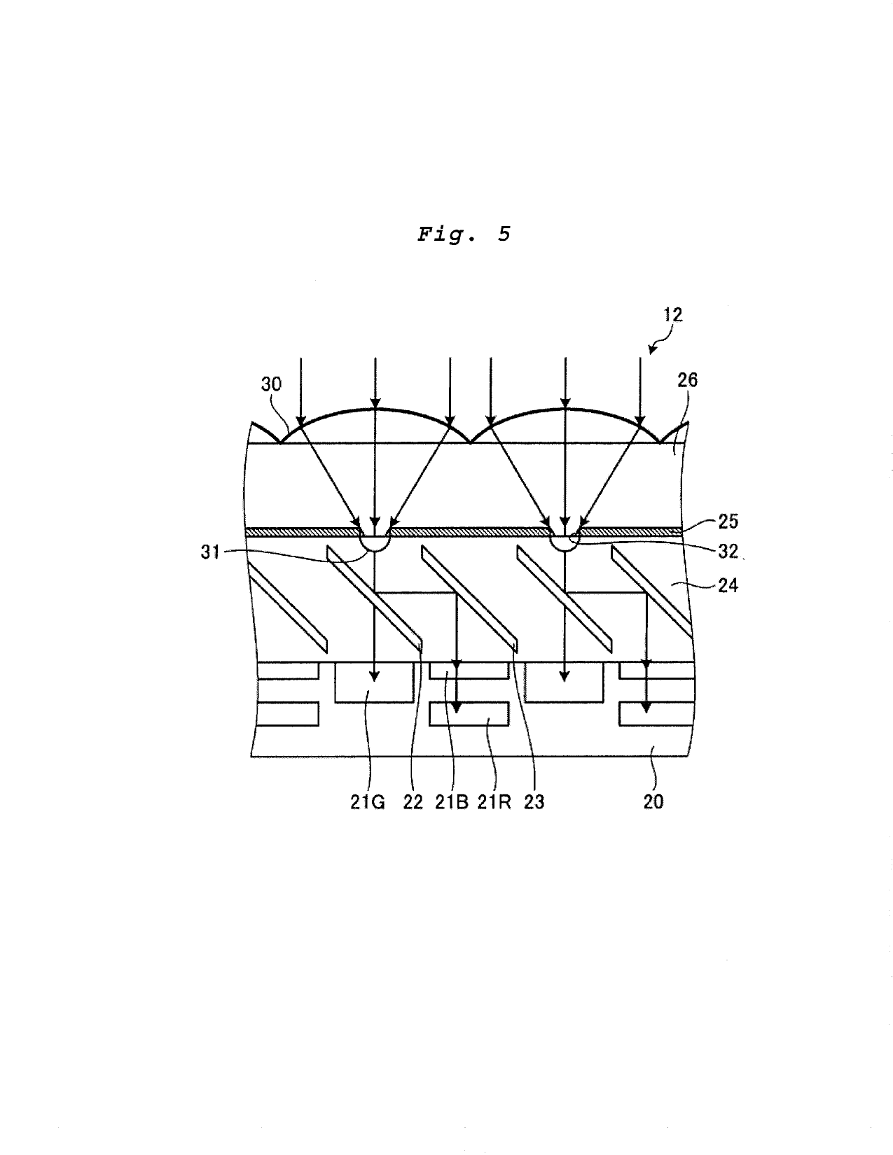

FIG. 5 is a schematic diagram explaining the behavior of light that enters the image sensor. The microlens 30 focuses incident light from the imaging optical system 11 towards the inner-layer lens 31. The inner-layer lens 31 makes the light from the microlens 30 parallel and forms a primary energy ray that is emitted from the inner-layer lens 31 along a straight line through the first transparent layer 24 towards the dichroic mirror 22.

Of the incident light in the primary energy ray, the dichroic mirror 22 transmits the G component, and reflects the R component and the B component. The G light that transmits through the dichroic mirror 22 travels in a straight line to the photoelectric conversion element 210 and is converted to a charge at the photoelectric conversion element 21G. The light that is reflected by the dichroic mirror 22 comprises a secondary energy ray consisting of wavelengths other than the wavelengths of the G component. In this example the secondary energy ray comprises the R component and the B component, and the light path of the R component and the B component is bent 90 degrees due to reflection at the dichroic mirror 22 and travels in a straight line towards the reflecting mirror 23.

The light path of the light that impinges the reflecting mirror 23 is bent 90 degrees due to reflection at the reflecting mirror 23, and travels in a straight line towards the photoelectric conversion element 21B. Of the light that enters the photoelectric conversion element 21B, the B component is converted to a charge at the photoelectric conversion element 21B. Of the light that enters the photoelectric conversion element 21B, the R component permeates the photoelectric conversion element 21B, and after traveling to the P-type layer of the semiconductor layer 20 is converted to a charge at the photoelectric conversion element 21R. The image sensor 12 guides the R light, G light, and the B light that are separated at the dichroic mirror 22 each to the photoelectric conversion elements 21R, 21G and 21B. The image sensor 12 can improve the light usage efficiency, when compared to adopting a filtering method of color separation in which colored rays, other than the colored rays that are guided to the photoelectric conversion elements 21R, 21G, and 21B, are absorbed by a color filter.

The image sensor 12 acquires information on each color component for each microlens 30 by corresponding one microlens 30 to a combination of photoelectric conversion elements 21R, 21G and 21B dedicated for each colored ray. By acquiring information on each color component regarding each microlens 30, the image sensor 12 can acquire color images without going through signal interpolation processing for each color component. The image sensor 12, by omitting color reproduction through interpolation techniques, makes it possible to acquire high quality images where false colors are greatly reduced.

The image sensor 12, by making the photoelectric conversion element 21B and 21R a stacked, laminate structure, makes it possible to secure a wide optical receiving surface for each photoelectric conversion element 21R, 21G, and 21B. The laminate structure is superior as opposed to juxtaposing the photoelectric conversion elements 21R, 21G, and 21B on a common plane. The image sensor 12 can achieve an increase in the number of saturated electrons at the photoelectric conversion elements 21R, 21G, and 21B, as well as an increase in the efficiency of light acquisition and an expansion in the production margins, which leads to greater resolution in images produced by the image sensor 12.

The image sensor 12, by first separating the G component of the medium wavelength band of the color components R, G, and B, interjects a P-type layer between two layers of photoelectric conversion elements 21B and 21R. In this manner, the image sensor 12 can effectively suppress the degradation of the color separation performance due to the overlap in the spectral characteristics, as opposed to interjecting the photoelectric conversion element 21G between the photoelectric conversion elements 21B and 21R.

The spectral sensitivity of the human eye peaks around the green wavelength region that is positioned in the middle wavelength regions of the wavelength band of visible light. Thus, of the individual RGB components, the G component most greatly affects that way an image looks. The image sensor 12 reduces the loss, especially of G light, by placing the photoelectric conversion element 21G where light from the microlens 30 travels in a straight line. The image sensor 12, by reducing the loss of G light and thus maintaining the resolution and SNR of the G component at a high level, makes it possible to achieve a signal having high resolution and low noise. The resulting signal provides superior resolution in an image produced by the image sensor 12.

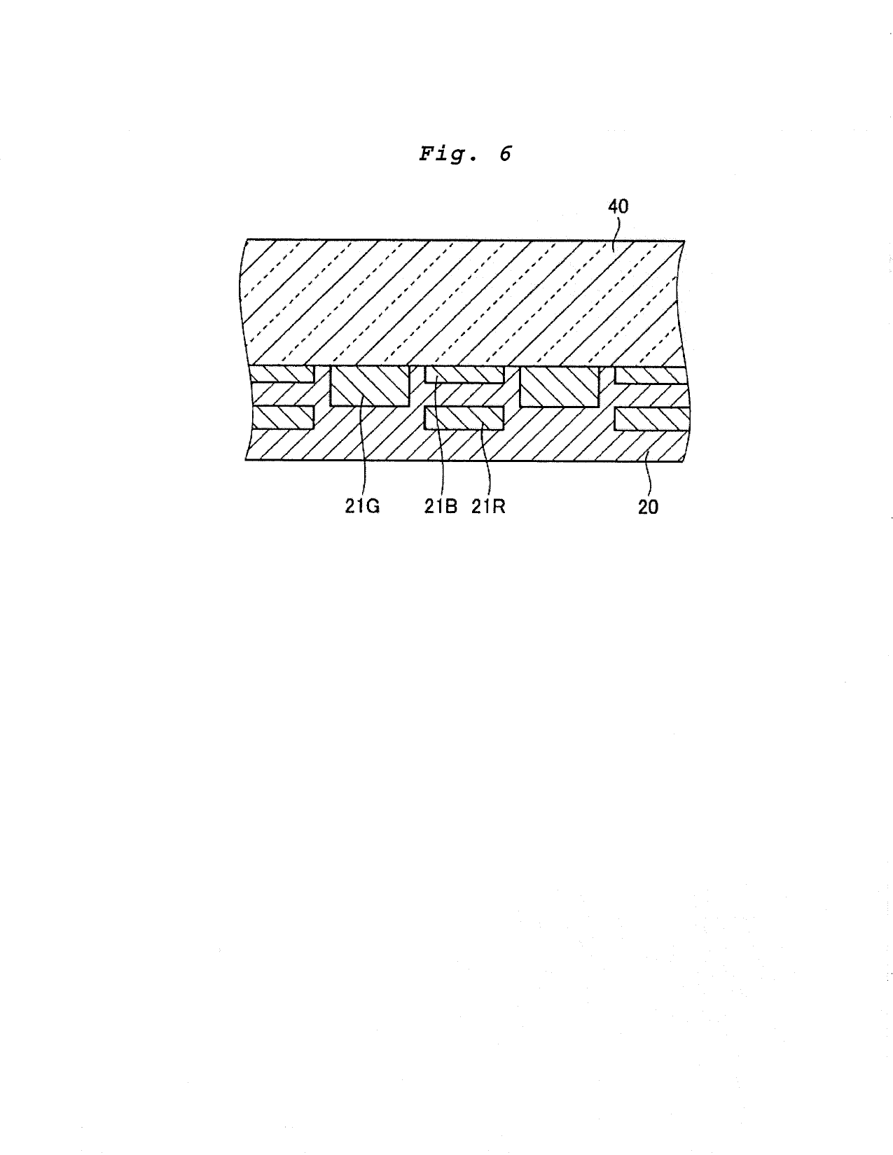

FIG. 6 through FIG. 8 are cross-sectional diagrams of the relevant elements that describe examples of a production procedure of the image sensor 12. In the process shown in FIG. 6, a resist layer 40, which is transparent and also a photosensitive material, is formed on top of the P-type semiconductor layer 20, on which is formed the photoelectric conversion elements 21R, 21G, and 21B which are N-type photodiodes. The resist layer 40 composes the first transparent layer 24 (shown in FIG. 1).

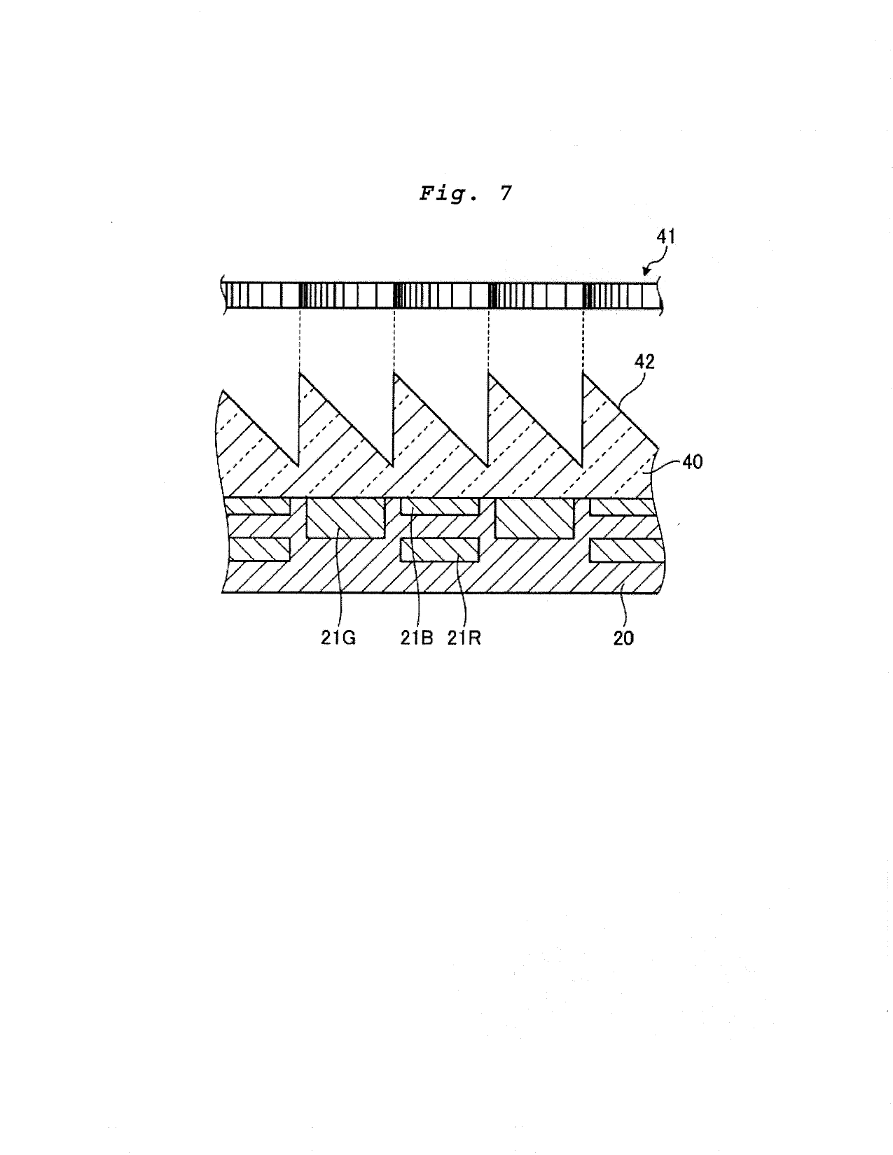

In the process shown in FIG. 7, the resist layer 40 is etched using a grating mask 41. The grating mask 41 is formed so that, for each unit area that amounts to a pixel, the pattern becomes denser as you go from right to left in the figure, for example. The regions where the pattern of the grating mask 41 are denser will have lower light transmittance and the exposure amount of the resist layer 40 is lessened in these higher density regions.

By the exposure of the resist layer 40 using the grating mask 41, a slope 42 with a right downward sloping tilt is formed for each area that amounts to a pixel. The density of the pattern on the grating mask 41 is dictated by the desired diffraction gradient for forming the dichroic mirror 22 and the reflecting mirror 23.

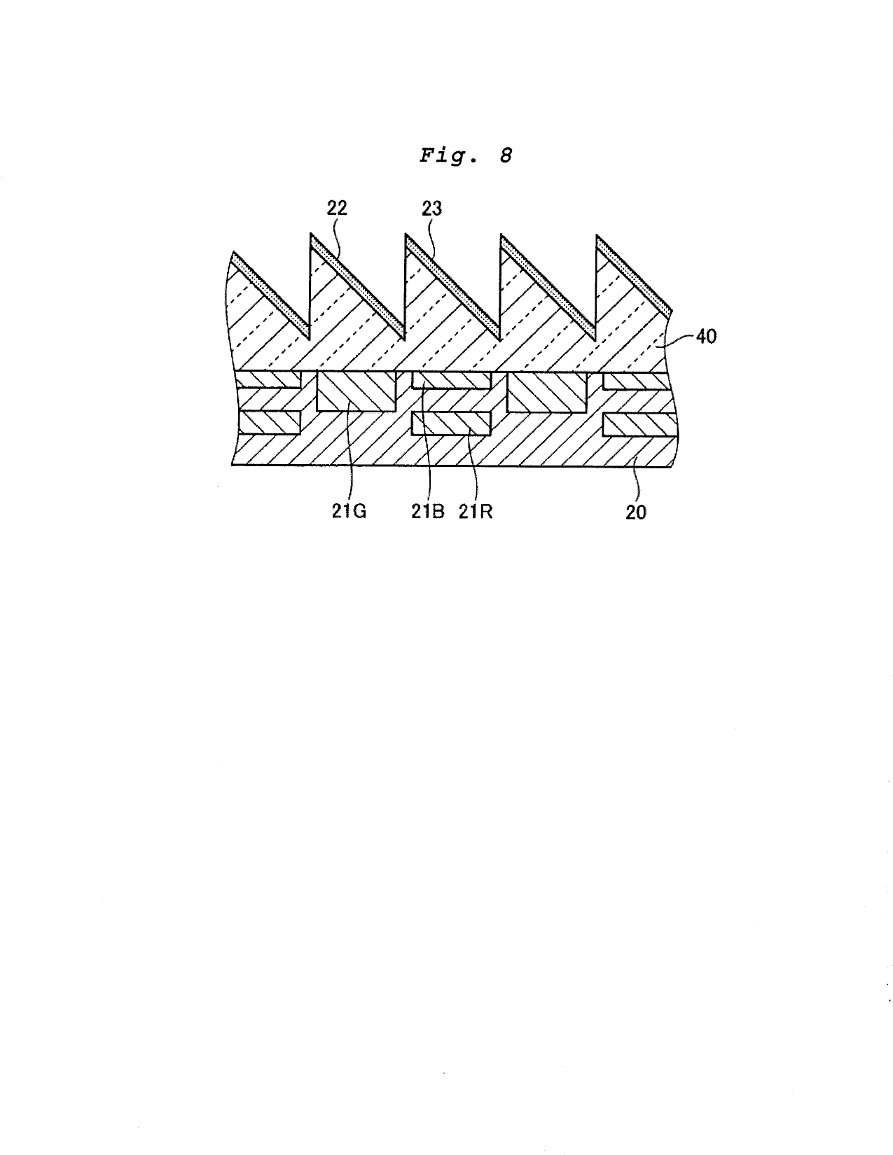

In the process shown in FIG. 8, the dichroic mirror 22 and the reflecting mirror 23 are formed on the slope 42 of the resist layer 40. By applying film with materials with different refraction indices on the slope 42 multiple times, a dichroic mirror 22 which is equipped with a multilayer structure of a thin film with different refraction indices is formed.

The multilayer film dichroic filter which composes the dichroic mirror 22 is equipped with a quarter wavelength (λ/4) multilayer film and a spacer layer that is sandwiched by the λ/4 multilayer film. The multilayer film dichroic filter allows light corresponding to an optical film thickness of the spacer layer to transmit. The configured wavelength λ is the central wavelength of the wavelength band of the light that is reflected at the λ/4 multilayer film. The λ/4 multilayer film is composed of the optical film thickness that corresponds to ¼ of the configured wavelength λ. For example, if the configured wavelength λ, is 550 nm, the optical film thickness of the dielectric layer that composes the λ/4 multilayer film will become 137.5 nm. The optical film thickness is an index that is acquired by taking the dielectric layer's physical film thickness and multiplying it by its refraction index.

In this embodiment, the dichroic mirror 22 is comprised of a composition wherein two types of dielectric layers having different refractive indices are formed in alternative stacked layers. For example, a high refractive layer, that is made of titanium oxide (e.g., TiO₂), and a low refractive layer that is made from silicon oxide (e.g., SiO₂), are layer-stacked in an alternating manner. By making the film thickness of a layer of TiO₂, which has a refractive index of 2.51, about 54.7 nm, will yield an optical film thickness of about 137.5 nm. By making the film thickness of a layer of SiO₂, which has a refractive index of 1.45, about 94.8 nm, will yield an optical film thickness 137.5 nm.

The spacer layer, which is sandwiched by the λ/4 multilayer film, is made of SiO₂. With the dichroic mirror 22 which transmits G light, the physical film thickness of the spacer layer may be about 0 nm. With the dichroic mirror 22 which transmits G light, the physical film thickness of the two layers of the TiO₂ layer that sandwich the spacer layer, may be about 109.4 nm in total. With the dichroic mirror 22 which transmits G light, the total number of layers that include the λ/4 multilayer film and the spacer layer may be about 6 layers to about 20 layers.

When forming a reflecting mirror 23 with the same wavelength selectivity as the dichroic mirror 22, the dichroic mirror 22 and the reflecting mirror 23 can be formed simultaneously. When forming a reflecting mirror 23 made from a high reflecting material without wavelength selectivity, the reflective mirror 23 will be formed separately from the dichroic mirror 22 via a process that corresponds to the desired reflectivity of the reflective mirror 23. As an example, the reflective mirror 23 may be formed by forming a film of aluminum on the slope 42 of the resist layer 40.

By applying the same transparent material as the resist layer 40 on top of the structure shown in FIG. 8, the first transparent layer 24 (shown in FIG. 1) is acquired, which seals the dichroic mirror 22 and the reflective mirror 23 therein. By placing the inner-layer lens 31 and the light shielding layer 25 (both shown in FIG. 1) in the first transparent layer 24, the image sensor 12 shown in FIG. 1 is acquired, via the formation of the second transparent layer 26 and the microlens array.

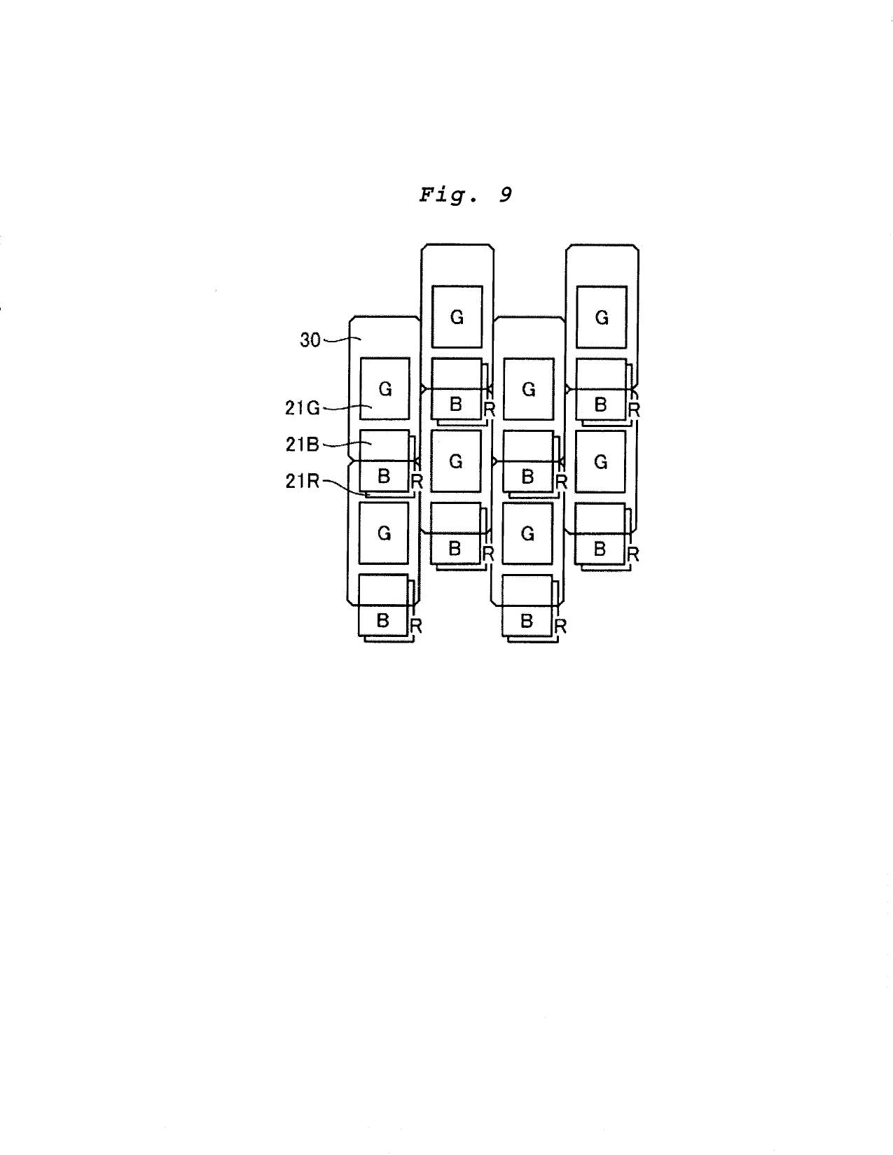

In another embodiment, the structure of the microlens array and the photoelectric conversion element array shown in FIG. 3 may be modified. FIG. 9 is a diagram showing a variant example of the microlens array and the photoelectric conversion element array. The microlens 30 forms an octagon with the corners slightly removed from a rectangle that is longer in the row direction. As in FIG. 3, the microlens 30 is shown as viewed from a slight angle on the incident light side of the image sensor 12 and the photoelectric conversion elements 21R, 21G, and 21B that are positioned below the microlens 30.

Even when the microlens 30 and the photoelectric conversion elements 21R, 21G and 21B are arranged as shown in FIG. 9, the image sensor 12 is able to acquire high quality images, the same as when they are arranged as shown in FIG. 3. In this variant example, each color signal for the column direction can be effectively separated, and the horizontal resolution is improved. In the variant example shown in FIG. 9, each microlens 30 can have, for example, a shape that is a rectangle with its four corners rounded, or a rectangle, an ellipse, etc. In this FIG., the microlens array is positioned so that the row direction (of each microlens 30) will be the longer dimension of the microlens 30. However, the microlens array may be positioned 90 degrees from the position shown in FIG. 9 such that the column direction (of each microlens 30) will be the longer dimension of the microlens 30.

Embodiments of the image sensor 12 has been shown and described with a dichroic mirror 22 that transmits the G light and reflects the R light and the B light. Alternatively, the image sensor 12 can be applied with a dichroic mirror 22 that transmits R light and B light and reflects G light.

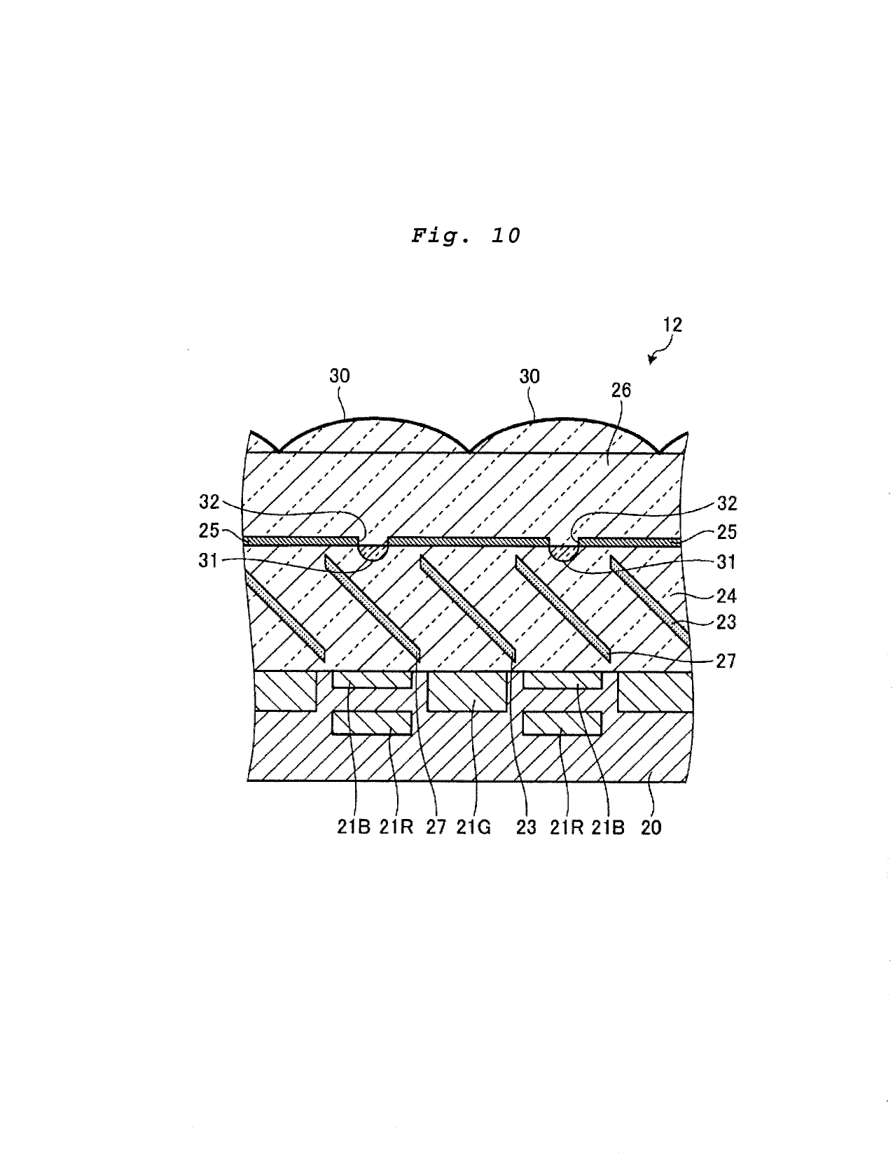

FIG. 10 is a cross-sectional diagram of a portion of another embodiment of an image sensor which may be utilized in a solid-state imaging device, such as the camera 10 of FIG. 2. The microlens 30 is arranged so that the position of the laminate structure of the photoelectric conversion elements 21R and 21B is near a center of each microlens 30. The microlens 30 is placed according to the extent that includes the optical receiving surface of the photoelectric conversion element 21B in the center and portions of the optical receiving surface of the photoelectric conversion element 21G that is adjacent to the photoelectric conversion element 21B in the column direction and the row direction.

When light enters from the inner-layer lens 31, the dichroic mirror 27, which is a color separator device, transmits the B light and the R light, and reflects the G light. The dichroic mirror 27 is placed along the path of the principle ray of light that travels from the inner-layer lens 31 to the photoelectric conversion element 21B that is above the photoelectric conversion element 21B. The dichroic mirror 27 is tilted so that the incidence plane is at a nearly 45 degree angle with respect to the principle ray of the light that enters from the microlens 30.

The reflective mirror 23, which is a reflector unit, is placed along the path of light that is reflected at the dichroic mirror 27 and is above the photoelectric conversion element 21G. The reflective mirror 23 is tilted so that the incidence plane is nearly a 45 degree angle with respect to the plane of the optical receiving surface of the photoelectric conversion element 21G. The incidence plane of the dichroic mirror 27 and the incidence plane of the reflective mirror 23 are nearly parallel.

The reflective mirror 23 reflects the G light that is reflected from the dichroic mirror 27 towards the photoelectric conversion element 21G. In the case of this variant example, the image sensor 12 makes it possible to produce photographs with high sensitivity and resolution, with high light usage efficiency. The construction of the image sensor 12 is also less costly to produce as compared to the manufacturing costs associated with conventional image sensors.

### EMBODIMENT 2

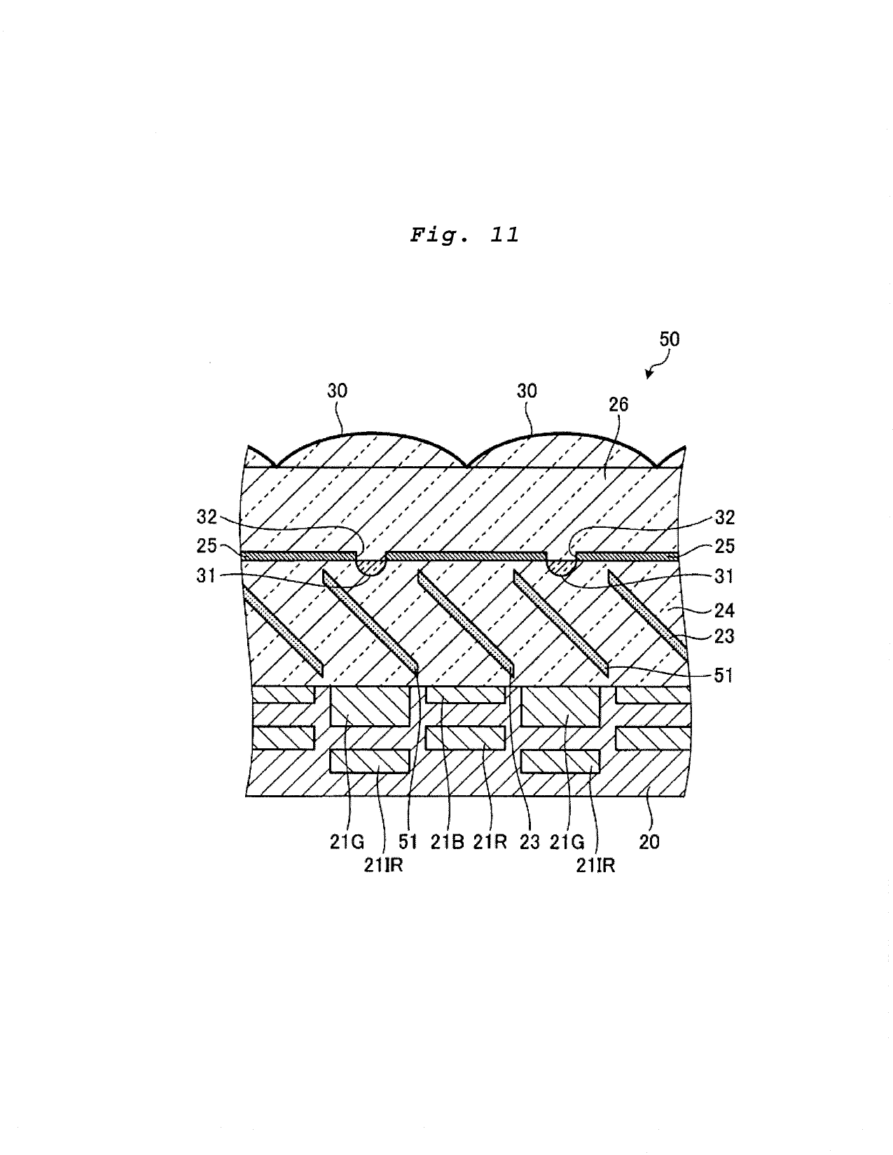

FIG. 11 is a cross section diagram of a portion of another embodiment of an image sensor 50 which may be used in a solid-state imaging device, such as the camera 10 of FIG. 2. In areas that are identical to the first embodiment, the same reference numerals are utilized, where applicable, and any overlapping explanation will be omitted for brevity. The image sensor 50 includes a photoelectric conversion element 21IR. The photoelectric conversion element 21IR is, for example, an N-type photodiode. The photoelectric conversion element 21IR is a photoelectric conversion element dedicated for infrared light, which detects infrared (IR) light. Additionally, a dichroic mirror 51 is utilized with the image sensor 50.

The camera module 10a (shown in FIG. 2) that is used with the image sensor 50 according to this embodiment should not be equipped with an IR cut filter, which eliminates the IR component from the light that travels to the image sensor 50. Also, when the image sensor 12 described in the first embodiment is to used with the camera module 10a, the camera module 10a may include an IR cut filter which eliminates IR light from the light that travels to the image sensor 12.

The photoelectric conversion elements 21G and 21IR form a stacked laminate structure that sandwiches the P-type layer. The photoelectric conversion element 21G is the N-type layer on the energy receiving side of the P-type semiconductor layer 20. The photoelectric conversion element 21IR is an N-type layer disposed below the photoelectric conversion element 21G. The laminate structure of the photoelectric conversion elements 21G is layer-stacked on the incidence side of the photoelectric conversion element 21IR. The photoelectric conversion element array comprises the laminate structure of the photoelectric conversion elements 21G and 21IR and the laminate structure of the photoelectric conversion elements 21R and 21B arranged laterally relative to each other into an array.

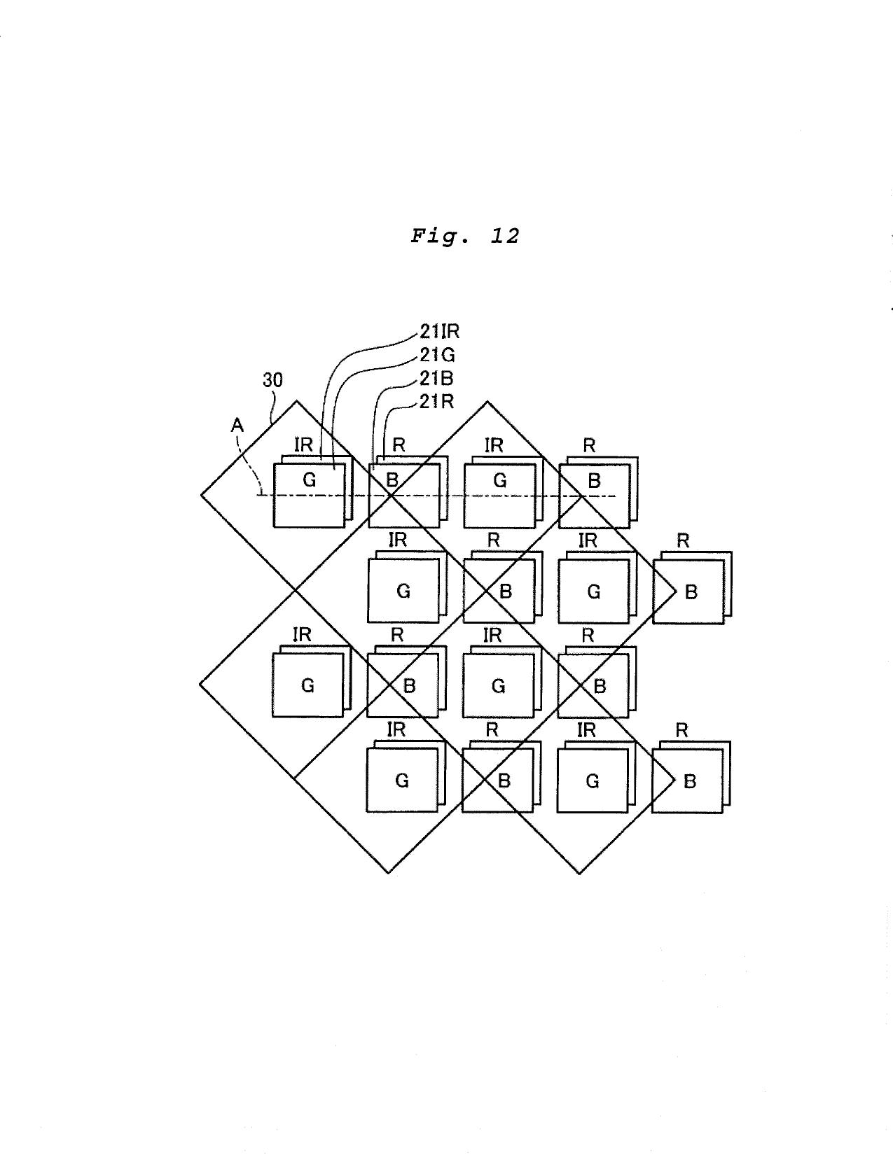

FIG. 12 is a schematic plan view showing positioning of the microlens array and the photoelectric conversion element array of FIG. 11. Here, the microlens 30 is shown when the image sensor 50 is viewed from a slight angle from the light incidence side, along with the photoelectric conversion elements 21R, 21G, 21B, and 21IR that are positioned below the microlens 30. Also, the cross-section shown in FIG. 11 corresponds to the cross-section at the dashed line A in FIG. 12.

The laminate structure comprising the photoelectric conversion elements 21G and 21IR and the laminate structure comprising the photoelectric conversion elements 21R and 21B are arranged laterally into a square array. The image sensor 50 is positioned so that one microlens 30 corresponds to a combination of photoelectric conversion elements 21R, 21G, 21B, and 21IR dedicated for each colored ray.

The dichroic mirror 51 and the reflective mirror 23 are placed in the first transparent layer 24. Of the light that enters, the dichroic mirror 51 transmits the G light and the IR light, and reflects the B light and the R light. The dichroic mirror 51 comprises a color separator unit that functions to separate light from the inner-layer lens 31. The dichroic mirror 51 is equipped with a dielectric multilayer comprising a layer of high refraction material and a layer of low refraction material in an alternating manner. The dichroic mirror 51 has the same composition and arrangement as the dichroic mirror 22 of the first embodiment (see FIG. 1), except for having a different wavelength characteristic.

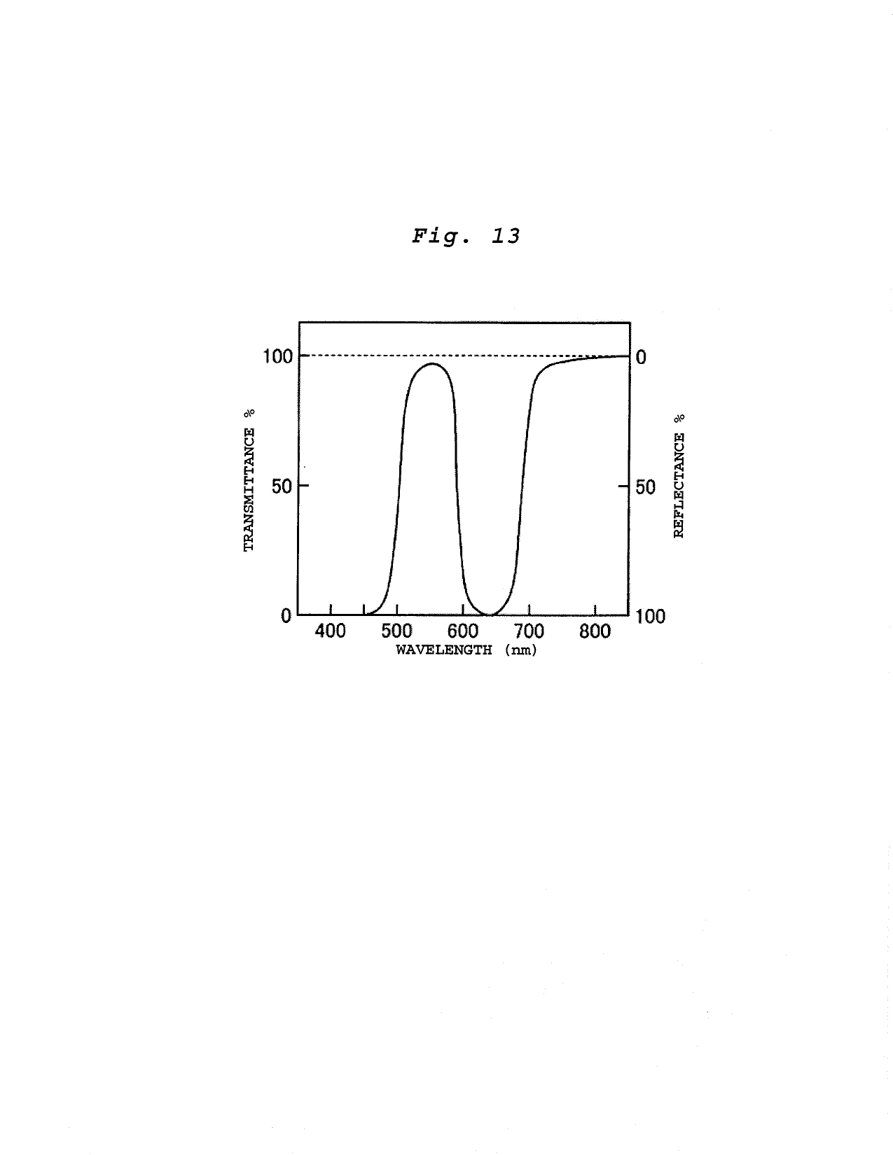

FIG. 13 is a graph showing an example of the spectral characteristic of the dichroic mirror 51. The dichroic mirror 51, for example, transmits G light in wavelengths from about 490 nm to about 580 nm and IR light having wavelengths that are longer than about 650 nm, and reflects B light having wavelengths shorter than about 490 nm and R light having wavelengths between about 580 nm and about 650 nm. The wavelengths illustrated by this example shall be the half-power wavelength with a 50% transmittance.

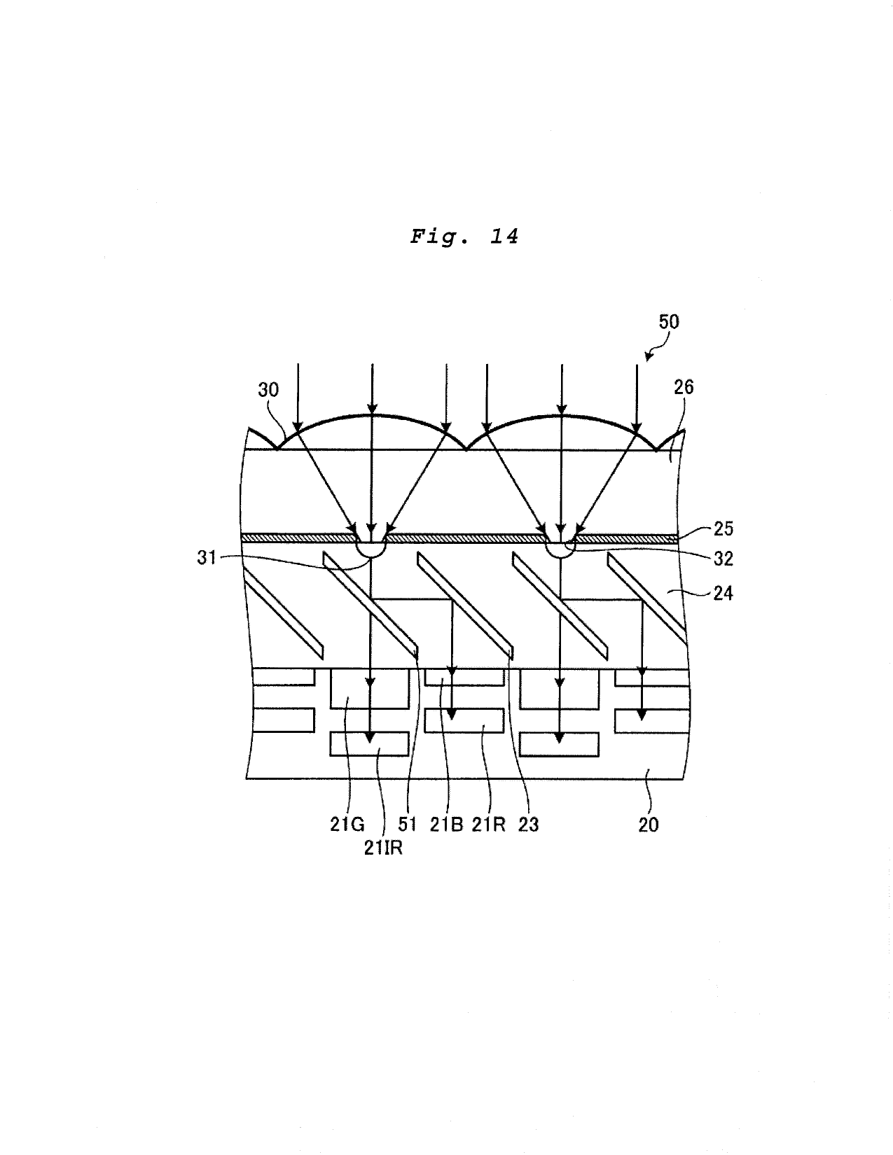

FIG. 14 is a schematic diagram explaining the behavior of light that enters the image sensor 50. The microlens 30 focuses the incident light towards the inner-layer lens 31. Light emitted from the inner-layer lens 31 travels in a straight line through the first transparent layer 24 towards the dichroic mirror 51.

A portion of the light that enters the first transparent layer 24 is transmitted the dichroic mirror 51 and a portion of the light is reflected. The dichroic mirror 51 transmits the G component and the IR component, and reflects the R component and the B component. The G light and the IR light that permeate the dichroic mirror 51, enters the photoelectric conversion element 21G. The G component of the light that enters the photoelectric conversion element 21G is converted into a charge at the photoelectric conversion element 21G. Within the portion of light that enters the photoelectric conversion element 21G, the IR component permeates the photoelectric conversion element 21G, travels through the P-type layer, and is converted into a charge at the photoelectric conversion element 21IR.

Within the portion of light that is reflected by the dichroic mirror 51, the light path of the R component and the B component are bent 90 degrees due to reflection in the dichroic mirror 51 and travels towards the reflective mirror 23. The light path that is reflected by the reflective mirror 23 is bent 90 degrees due to the reflection in the reflective mirror 23 and travels towards the photoelectric conversion element 21B. The B component of the light that enters the photoelectric conversion element 21B is converted into a charge at the photoelectric conversion element 21B. The R component of the light that enters the photoelectric conversion element 21B permeates the photoelectric conversion element 21B, travels through the P-type layer, and is converted into a charge at the photoelectric conversion element 21R.

The image sensor 50, by being equipped with the same composition as the first embodiment, makes it possible to perform high sensitivity photography with a high light usage efficiency and decreased manufacturing costs, like the first embodiment. The image sensor 50, for example, allows high sensitivity in low light environments by adding the signal detected at the photoelectric conversion element 21IR as brightness information. Also with this embodiment, a camera for color photography and a security camera that uses IR light can be realized with the application of the image sensor 50. If, for example, that the four pixels of R, G, B, and IR are arranged as 2×2 pixels on a plane and are made a unit of a pixel array, the resolution of G will be one half of the total resolution of the image sensor 50. The image sensor 50 of this embodiment can suppress the decrease of the resolution by acquiring information on each color component for each microlens 30.

Also, in the case of arranging the four pixels of R, G, B, and IR on a plane into 2×2 pixels, there are times when interpolation processes are conducted in order to eliminate IR signals that are mixed into the R, G, and B signals. The interpolation processes in such a case may cause a decrease in color reproducibility and a degradation of SNR. In this embodiment, the image sensor 50 does not utilize this type of interpolation process and, instead, detects each R, G, and B color component that is separated from the IR component, so it makes possible a good color reproducibility and also suppresses degradation of SNR.

The image sensor 50, like the image sensor 12 (see FIG. 10) that pertains to the variant example of the first embodiment, can have a composition that is applied a dichroic mirror that permeates the B light and the R light and reflects the G light.

In this case, the microlens 30 is arranged so that the position of the laminate structure of the photoelectric conversion elements 21R and 21B is at the center of a microlens 30. The dichroic mirror is placed along the path of light that travels from the inner-layer lens 31 to the photoelectric conversion element 21B and is above the photoelectric conversion element 21B. The dichroic mirror permeates B light and R light, while reflecting the G light and IR light.

The reflective mirror 23 is placed along the path of light that is reflected by the dichroic mirror and is above the photoelectric conversion element 21G. The reflective mirror 23 reflects the G light and the IR light reflected from the dichroic mirror towards the photoelectric conversion element 21G. Even with such a composition, the image sensor 50 makes possible high-sensitivity photography utilizing the high light usage efficiency while realizing a decrease in manufacturing costs.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device, comprising:
an optical lens array overlying a color separation layer which overlies a semiconductor layer, the semiconductor layer comprising a plurality of photoelectric conversion elements disposed in a repeating pattern in the semiconductor layer, each of the plurality of photoelectric conversion elements comprising:
a first photoelectric conversion element dedicated to detection of energy in a first wavelength range;
a second photoelectric conversion element dedicated to detection of energy in a second wavelength range; and
a third photoelectric conversion element dedicated to detection of energy in a third wavelength range, wherein:
each of the first, the second, and the third wavelength ranges are different; and
the first photoelectric conversion element overlies the second or the third photoelectric conversion elements which requires energy to travel through the first photoelectric conversion element before being detected by the second or the third photoelectric conversion elements.

2. The device of claim 1, wherein the color separation layer further comprises:
a plurality of mirrors disposed in a primary ray path from the optical lens array.

3. The device of claim 2, wherein the plurality of mirrors comprises a first mirror configured to transmit one of the wavelength ranges therethrough, and reflect other wavelength ranges.

4. The device of claim 3, wherein the plurality of mirrors comprises a second mirror configured to reflect the other wavelength ranges.

5. The device of claim 1, wherein the second photoelectric conversion element is dedicated to a wavelength that is longer than the third wavelength range and the second wavelength range.

6. The device of claim 1, wherein the first photoelectric conversion element overlies the second photoelectric conversion element, and the second photoelectric conversion element is dedicated to a wavelength that is longer than the third wavelength range and the second wavelength range.

7. The device of claim 6, wherein the third photoelectric conversion element is laterally spaced from the first photoelectric conversion element and the second photoelectric conversion element.

8. The device of claim 1, wherein the plurality of photoelectric conversion elements further comprises:
a fourth photoelectric conversion element dedicated to a fourth wavelength range that is greater than the first, the second, and the third wavelength range, wherein the first photoelectric conversion element overlies the second photoelectric conversion element and the third photoelectric conversion element overlies the fourth photoelectric conversion element.

9. A method for detecting energy in an optical imaging device, the method comprising:
providing a semiconductor layer;
forming a plurality of photoelectric conversion elements on the semiconductor layer, each of the plurality of photoelectric conversion elements comprising:
a first photoelectric conversion element dedicated to detection of energy in a first wavelength range;
a second photoelectric conversion element dedicated to detection of energy in a second wavelength range that is different than the first wavelength range; and
a third photoelectric conversion element dedicated to detection of energy in a third wavelength range that is different than either of the first wavelength range and the second wavelength range;
positioning the first photoelectric conversion element to overlie the second or the third photoelectric conversion elements; and
directing energy to travel through the first photoelectric conversion element before being detected by the second or the third photoelectric conversion elements.

10. The method of claim 9, wherein the optical lens array comprises a plurality of microlenses, and the directing the energy further comprises:
directing a primary ray of incident energy through a center of each microlens in a substantially straight line to one of the first, the second, or the third photoelectric conversion elements.

11. The method of claim 10, wherein the directing the energy further comprises:
placing a mirror element in a path of the primary ray.

12. The method of claim 11, wherein the mirror element transmits a portion of the primary ray to the second or the third photoelectric conversion elements.

13. The method of claim 12, wherein a portion of the primary ray is reflected prior to transmittal to the second or the third photoelectric conversion element.

14. The method of claim 10, wherein the first photoelectric conversion element overlies the second photoelectric conversion element, and the directing the energy further comprises:
transmitting a portion of the primary ray through a first mirror element to the first photoelectric conversion element; and
reflecting a portion of the primary ray to a second mirror to the third photoelectric conversion element.

15. The method of claim 10, wherein the first photoelectric conversion element overlies the third photoelectric conversion element, and the directing the energy further comprises:
transmitting a portion of the primary ray through a first mirror element to the second photoelectric conversion element ; and
reflecting a portion of the primary ray to a second mirror to the first photoelectric conversion element.

16. The method of claim 15, wherein the first wavelength range is less than the second wavelength range, and the third wavelength range is greater than the second wavelength range.

17. The method of claim 10, wherein the plurality of photoelectric conversion elements further comprise a fourth photoelectric conversion element dedicated to a fourth wavelength range that is different than the first, the second, and the third wavelength range, and wherein the first photoelectric conversion element overlies the second photoelectric conversion element and the third photoelectric conversion element overlies the fourth photoelectric conversion element, and the directing the energy further comprises:
transmitting a portion of the primary ray through a first mirror element to the first photoelectric conversion element and the second photoelectric conversion element; and
reflecting a portion of the primary ray to a second mirror to the third photoelectric conversion element.

18. A method for manufacturing a solid-state imaging device, comprising:
forming a transparent layer between a microlens array and a plurality of photoelectric conversion elements formed in a semiconductor layer, wherein at least one of the plurality of photoelectric conversion elements overlies another of the plurality of photoelectric conversion elements; and
forming a color separation layer in the transparent layer, wherein the color separation layer comprises a plurality of first mirrors and a plurality of second mirrors, the plurality of first mirrors configured to transmit a specific wavelength range and reflect other wavelength ranges to one of the plurality of second mirrors.

19. The method of claim 18, wherein the plurality of first mirrors alternate with the plurality of second mirrors.

20. The method of claim 18, wherein the plurality of first mirrors are at about a 45 degree angle relative to the light receiving surface of the plurality of photoelectric conversion elements.
